(19) United States
(12) Patent Application Publication
(10) Pub. No.: US 2026/0011675 A1
(43) Pub. Date: Jan. 8, 2026

(54) FAN-OUT WAFER LEVEL PACKAGING UNIT

(71) Applicant: WALTON ADVANCED ENGINEERING, INC., KAOHSIUNG (TW)

(72) Inventors: HONG-CHI YU, KAOHSIUNG (TW); CHUN-JUNG LIN, KAOHSIUNG (TW); RUEI-TING GU, KAOHSIUNG (TW)

(21) Appl. No.: 19/250,084

(22) Filed: Jun. 26, 2025

(30) Foreign Application Priority Data
Jun. 28, 2024 (TW) 113124297

(51) Int. Cl. H01L 23/00; H01L 25/03

(52) U.S. Cl. CPC H01L 24/24; H01L 24/16; H01L 24/32; H01L 24/73; H01L 25/03; H01L 2224/16227; H01L 2224/24146; H01L 2224/244; H01L 2224/32225; H01L 2224/73267

(57) ABSTRACT

A fan-out wafer-level packaging (FOWLP) unit including a substrate, at least one first die, a first dielectric layer, a plurality of first conductive circuits, a second dielectric layer, a plurality of second conductive circuits, and at least one second die is provided. A range perpendicular to a second surface of the first die is defined as a chip area. The second dielectric layer is provided with a plurality of second slots allowing the second conductive circuit to expose and form bonding pads. The bonding pads located around the chip area are first bonding pads. The second die is disposed over the second dielectric layer by flip chip and electrically connected to the first die which is electrically connected with the outside by the first bonding pads. Thereby problems of conventional FOWLP generated during manufacturing of the conductive circuits including higher manufacturing cost and less environmental benefit can be solved.

### CROSS-REFERENCE TO RELATED APPLICATIONS

This non-provisional application claims priority under 35 U.S.C. § 119 (a) on Patent Application No(s). 113124297 filed in Taiwan, R.O.C. on Jun. 28, 2024, the entire contents of which are hereby incorporated by reference.

### BACKGROUND OF THE INVENTION

The present invention relates to a packaging unit, especially to a fan-out wafer level packaging (FOWLP) unit.

Packaging technology with features of compact design, high efficiency, and high reliability is a trend in semiconductor industry. In the semiconductor packaging, Fan-Out Wafer Level Packaging (FOWLP) is a packaging technology available now.

In the advanced packaging process such as FOWLP, a redistribution layer (RDL) is the most critical because respective conductive circuits in the RDL make a plurality of die pads on dies have electrical extension in the XY plane and interconnections. Thus a plurality of bonding pads is arranged around the die in a more distributed manner. Thereby design, space, and reliability of the respective conductive circuits are effectively improved. Yet how to keep balance between the electrical extension in the XY plane and interconnections of the conductive circuits and the compact design to a certain degree, the most critical point is the manufacturing of the respective conductive circuits in the RDL.

However, the formation of the respective conductive circuits in the RDL of the FOWLP technology available now is by chemical plating or electroplating. Thus not only cost for material and manufacturing is high, the manufacturing process is also not environmental friendly.

Moreover, the amount of dies must be increased in order to increase performance or computation ability of a FOWLP unit. How to form electrical connection between dies inside a packaging unit and the outside as well as dies outside the packaging unit and the inside is also a critical issue which needs to be addressed.

### SUMMARY OF THE INVENTION

Therefore, it is a primary object of the present invention to provide a fan-out wafer-level packaging (FOWLP) unit which includes a substrate, at least one first die, a first dielectric layer, a plurality of first conductive circuits, a second dielectric layer, a plurality of second conductive circuits, and at least one second die. A range perpendicular to a second surface of the first die is defined as a chip area. The second dielectric layer is provided with a plurality of second slots allowing the respective second conductive circuit to expose and form bonding pads. The bonding pads located around the chip area are first bonding pads. The second die is disposed over the second dielectric layer by flip chip and electrically connected to the first die. The first die is electrically connected with the outside by the first bonding pads. Thereby the problems of the FOWLP technology available now generated during manufacturing of the respective conductive circuits including higher manufacturing cost and less environmental benefit can be solved.

In order to achieve the above object, a FOWLP unit according to the present invention includes a substrate, at least one first die, a first dielectric layer, a plurality of first conductive circuits, a second dielectric layer, a plurality of second conductive circuits, and at least one second die. The first die is cut from a wafer and provided with a first surface and a second surface opposite to the first surface. The first surface of the first die is fixed on the substrate while the second surface of the first die is provided with a plurality of die pads. A range perpendicular to the second surface of the first die is defined as a chip area. The first dielectric layer is mounted to the substrate and the second surface of the first die and provided with a plurality of first slots extending in a horizontal direction. The respective die pads of the first die are exposed through the respective first slots. The respective first conductive circuits are formed by a metal paste filled in the respective first slots and electrically connected with the respective die pads of the first die. The second dielectric layer is disposed over the first dielectric layer and provided with a plurality of second slots each of which is extending in a horizontal direction and communicating with the corresponding first slot. The respective second conductive circuits are formed by a metal paste filled in the respective second slots and electrically connected with the first conductive circuits. The second slots are used for allowing the respective second conductive circuits to expose and form bonding pads in the second slots. Each of the bonding pads formed in the second slot around the chip area on the second surface of the first die is a first bonding pad which is electrically connected with the first conductive circuit located around the chip area. Each of the bonding pad formed in the second slot in the chip area on the second surface of the first die is a second bonding pad which is electrically connected with the first conductive circuit located in the chip area. The second die is cut from a wafer and provided with a first surface and a second surface opposite to the first surface. The second surface of the second die is provided with at least two die pads. At least two of the die pads of the second die are electrically connected to and disposed on at least two of the second bonding pads by flip chip so that the second die is located over the second dielectric layer and electrically connected with the first die by the first conductive circuits in the chip area of the first die. The first die is electrically connected to the outside through the respective die pads of the first die, the respective first conductive circuits located around the chip area, the respective second conductive circuits, and the first bonding pads located around the chip area on the second surface of the first die in turn. Thereby the FOWLP unit is formed. A method of manufacturing the FOWLP unit includes the following steps. Step S1: providing a substrate. Step S2: arranging a plurality of first dies cut from at least one wafer on the substrate with an interval between the two adjacent first dies. Each of the first dies includes a first surface and a second surface opposite to the first surface. The first surface of the first die is disposed on the substrate while the second surface of the first die is provided with a plurality of die pads. A range perpendicular to the second surface of the first die is defined as a chip area. Step S3: producing a plurality of first conductive circuits on the second surface of the first dies by filling a metal paste into slots and grinding the metal paste. First paving a first dielectric layer over the substrate and the second surface of the respective dies, forming a plurality of first slots horizontally on the first dielectric layer, and exposing the die pads of the first dies through the first slots. Then filling a metal paste into the respective first slots and allowing a level of the metal paste higher than a surface of the first dielectric layer. Lastly, grinding the metal paste with the level higher than the surface of the first dielectric layer to make a surface of the metal paste flush with the surface of the first dielectric layer and form a plurality of the first conductive circuits. Step S4: producing a plurality of second conductive circuits on the first dielectric layer by filling a metal paste into slots and grinding the metal paste. First paving a second dielectric layer over the first dielectric layer, forming a plurality of second slots horizontally on the second dielectric layer, and communicating the second slots with the first slots. Then filling a metal paste into the respective second slots and allowing a level of the metal paste higher than a surface of the second dielectric layer. Lastly, grinding the metal paste with the level higher than the surface of the second dielectric layer to make a surface of the metal paste flush with the surface of the second dielectric layer and form a plurality of the second conductive circuits. The second conductive circuits are exposed through the second slots to form bonding pads in the respective second slots. Each of the bonding pads formed in the second slots around the chip area on the second surface of the first die is a first bonding pad which is electrically connected with the corresponding first conductive circuit located around the chip area. Each of the bonding pads formed in the second slots in the chip area on the second surface of the first die is a second bonding pad which is electrically connected with the corresponding first conductive circuit located in the chip area. Step S5: disposing a plurality of second dies cut from at least one wafer over the second dielectric layer by flip chip with an interval between the two adjacent second dies. The second die includes a first surface and a second surface opposite to each other. The second surface of the second die is provided with at least two die pads which are electrically connected with at least two of the second bonding pads by flip chip. And the second dies are electrically connected with the first dies by the first conductive circuits in the chip area. Step S6: performing cutting to form a plurality of the FOWLP units.

Preferably, the first die and the second die are cut from the same wafer or different wafers.

Preferably, the substrate includes silicon (Si) substrate, glass substrate, and ceramic substrate.

Preferably, the metal pastes of the first conductive circuits and the second conductive circuits include silver paste, nano-scale silver paste, copper paste, and nano-scale copper paste.

Preferably, the first surface of the first die is disposed on the substrate by a die attach film (DAF).

Preferably, the die pads of the respective second dies are electrically connected to the at least two bonding pads by a solder ball.

Preferably, a solder ball is disposed on each of the second slots and electrically connected to the bonding pad in the second slot.

Preferably, the FOWLP unit is electrically connected and mounted to a printed circuit board (PCB) by the solder balls.

### BRIEF DESCRIPTION OF THE DRAWINGS

FIG. 1 is a side sectional view of an embodiment of a FOWLP unit according to the present invention;

FIG. 2 is a side sectional view of a substrate according to the present invention;

FIG. 3 is a side sectional view showing a first dielectric layer paved on a substrate of the embodiment in FIG. 2 according to the present invention;

FIG. 4 is a side sectional view showing first slots filled with a metal paste of the embodiment in FIG. 3 according to the present invention;

FIG. 5 is a side sectional view showing grinding of the metal paste with a level higher than a surface of the first dielectric layer of the embodiment in FIG. 4 according to the present invention;

FIG. 6 is a side sectional view showing a second dielectric layer disposed on a first dielectric layer of the embodiment in FIG. 5 according to the present invention;

FIG. 7 is a side sectional view showing second slots filled with a metal paste of the embodiment in FIG. 6 according to the present invention;

FIG. 8 is a side sectional view showing grinding of the metal paste with a level higher than a surface of the second dielectric layer of the embodiment in FIG. 7 according to the present invention;

FIG. 9 is a side sectional view showing a second die disposed over the second dielectric layer by flip chip of the embodiment in FIG. 8 according to the present invention;

FIG. 10 is a side sectional view showing solder balls disposed on second slots of the embodiment in FIG. 9 according to the present invention.

### DETAILED DESCRIPTION OF THE PREFERRED EMBODIMENT

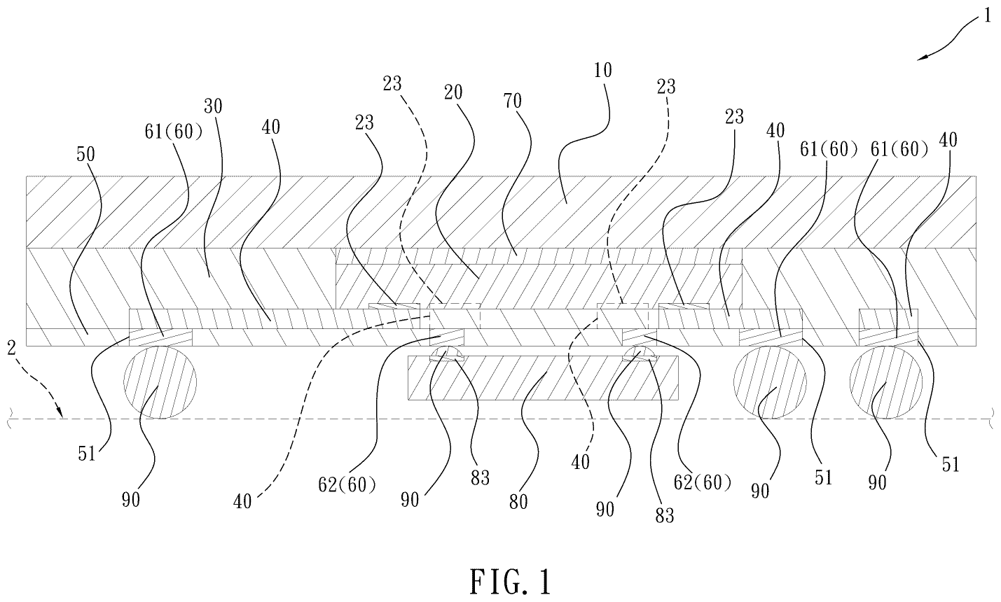

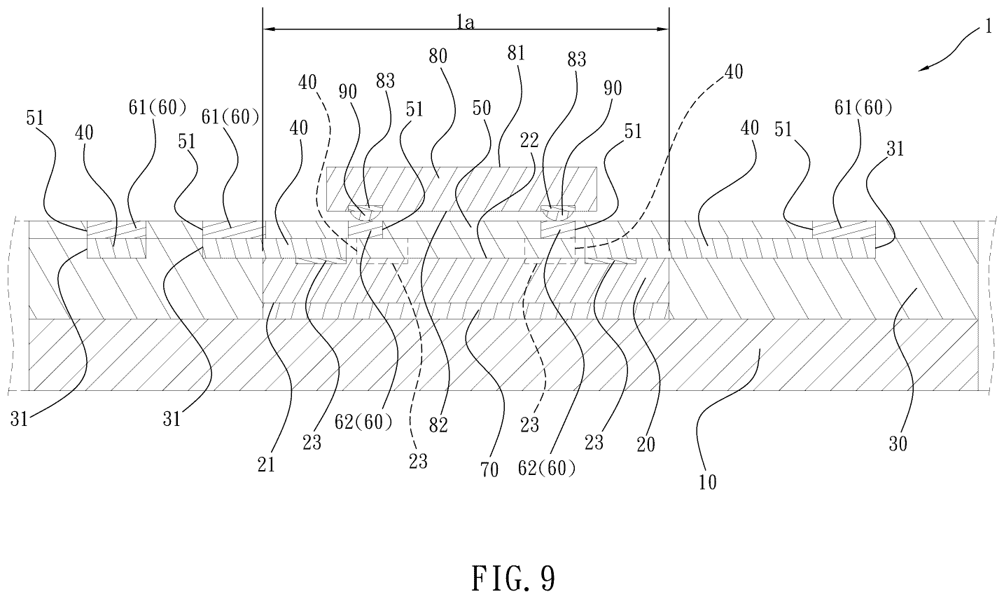

Refer to FIG. 1 and FIG. 9, a fan-out wafer-level packaging (FOWLP) unit 1 according to the present invention includes a substrate 10, at least one first die 20, a first dielectric layer 30, a plurality of first conductive circuits 40, a second dielectric layer 50, a plurality of second conductive circuits 60, a die attach film (DAF) 70, and at least one second die 80.

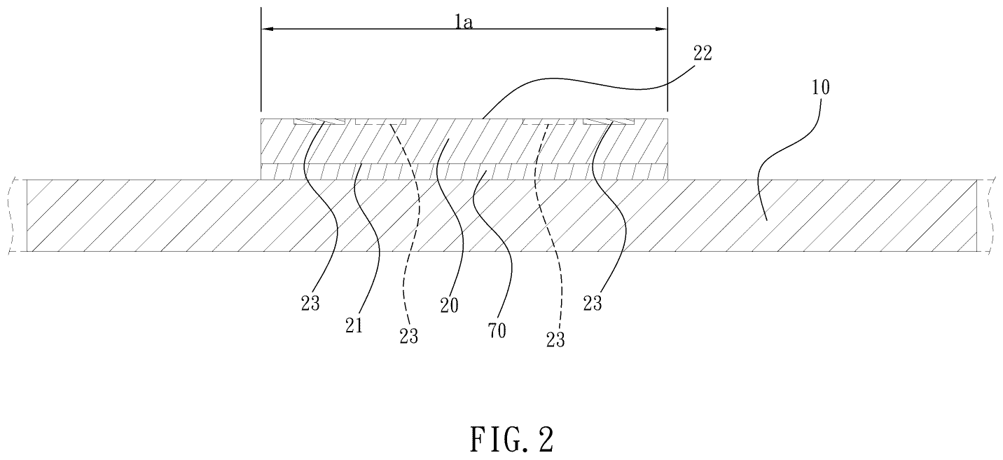

The first die 20 is cut from a wafer and provided with a first surface 21 and a second surface 22 opposite to the first surface 21. The first surface 21 of the first die 20 is fixed on the substrate 10 while the second surface 22 of the first die 20 is provided with a plurality of die pads 23. As shown in FIG. 2, a range perpendicular to the second surface 22 of the first die 20 is defined as a chip area 1a. The first surface 21 of the first die 20 is fixed on the substrate 10 by the DAF 70, as shown in FIG. 2. In FIG. 2, there are four die pads 23 on the first die 20 but the number of the die pads 23 is not limited.

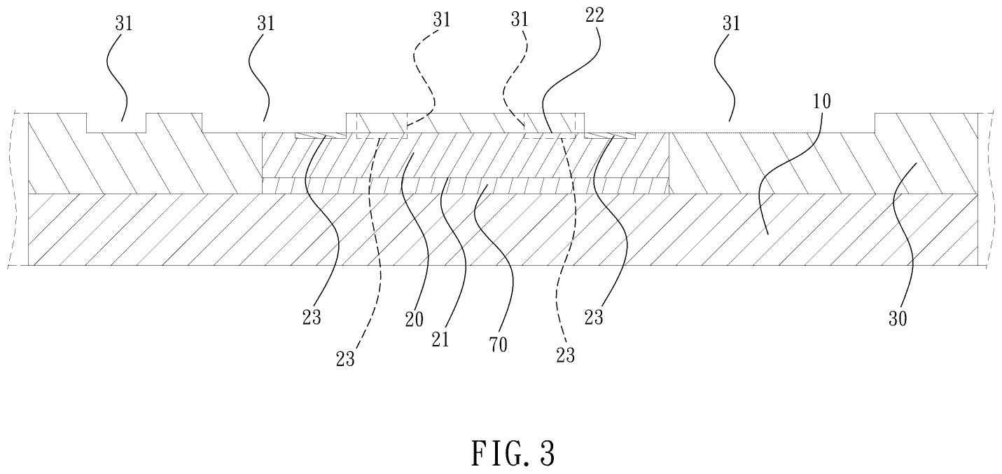

As shown in FIG. 3, the first dielectric layer 30 is mounted to the substrate 10 and the second surface 22 of the first die 20 and provided with a plurality of first slots 31 extending in a horizontal direction. The respective die pads 23 of the first die 20 are exposed through the respective first slots 31.

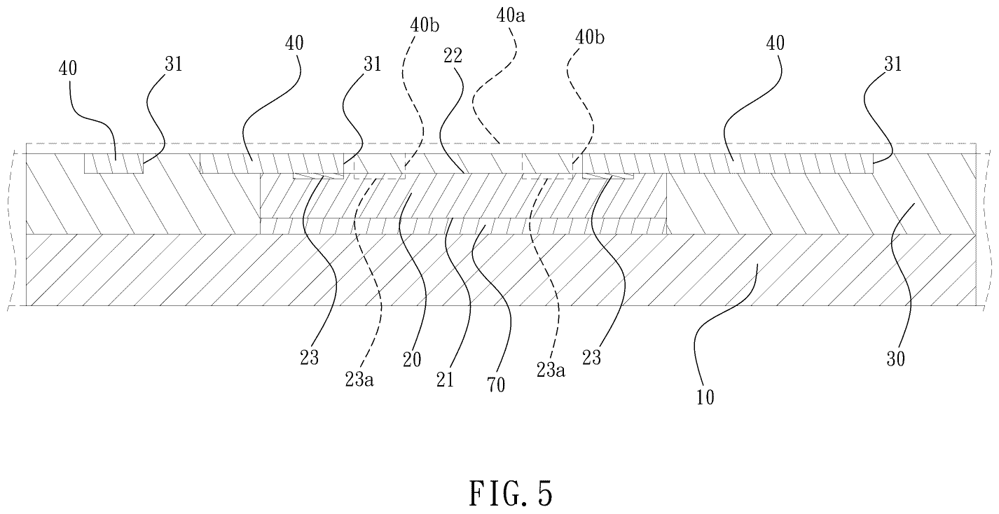

The respective first conductive circuits 40 are formed by a metal paste 40a filled in the respective first slots 31. As shown in FIG. 5, the respective first conductive circuits 40 are electrically connected with the respective die pads 23 of the first die 20.

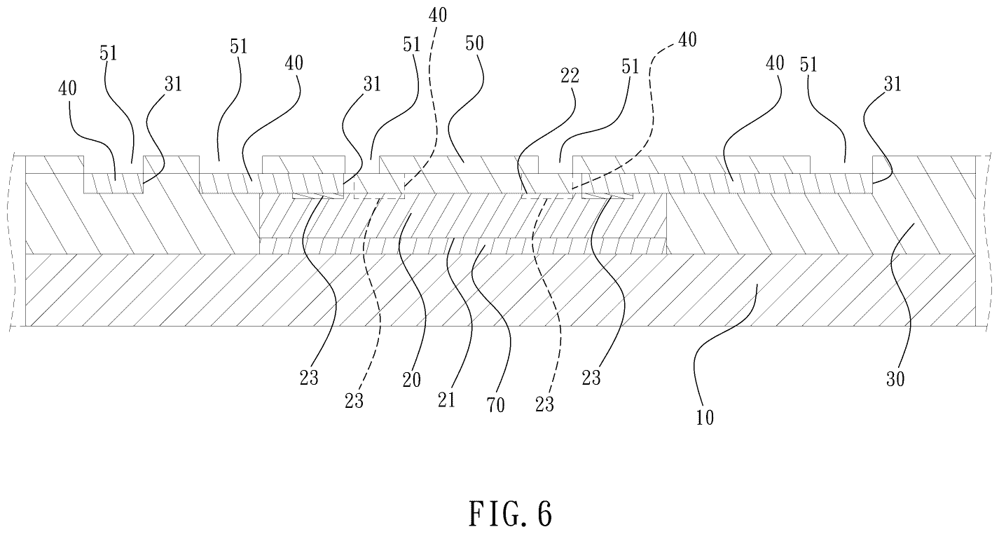

The second dielectric layer 50 is disposed over the first dielectric layer and provided with a plurality of second slots 51 each of which is extending in a horizontal direction and communicating with the corresponding first slot 31, as shown in FIG. 6.

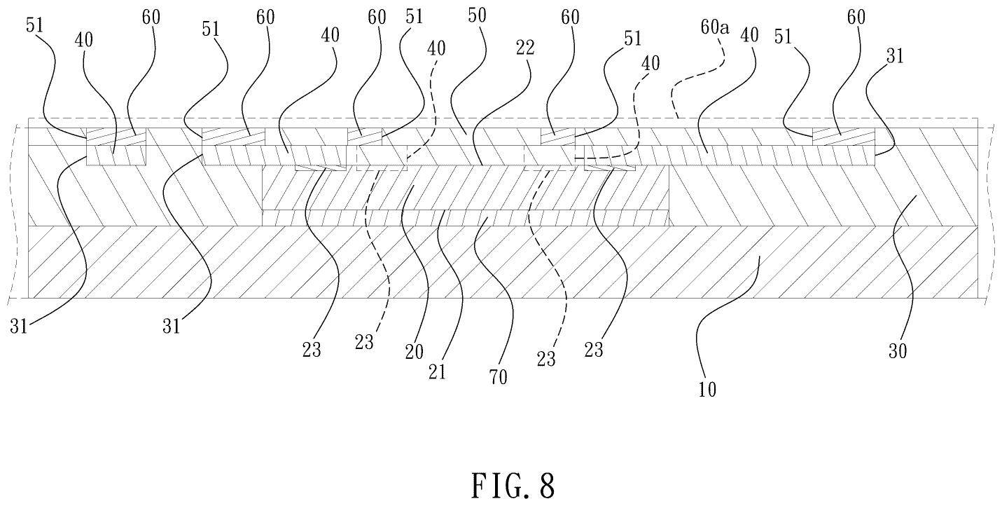

The respective second conductive circuits 60 are formed by a metal paste 60a filled in the respective second slots 51 and electrically connected with the first conductive circuits 40, as shown in FIG. 8. A bonding pad formed in the second slot 51 around the chip area 1a on the second surface 22 of the first die 20 is a first bonding pad 61 which is electrically connected with the first conductive circuit 40 located around the chip area 1a of the first die 20, as shown in FIG. 9. A bonding pad formed in the second slot 51 in the chip area 1a on the second surface 22 of the first die 20 is a second bonding pad 62 which is electrically connected with the first conductive circuit 40 located in the chip area 1a of the first die 20, as shown in FIG. 9.

The second die 80 is cut from a wafer and provided with a first surface 81 and a second surface 82 opposite to the first surface 81. The second surface 82 of the second die 80 is provided with at least two die pads 83, as shown in FIG. 9. At least two of the die pads 83 of the second die 80 are electrically connected to and disposed on at least two of the second bonding pads 62 by flip chip so that the second die 80 is located over the second dielectric layer 70 and is electrically connected with the first die 20 by the first conductive circuit 40 in the chip area 1a of the first die 20. In FIG. 9, the second die 80 includes two die pads 83 and the number of the die pad 83 is not limited. This is only an example, not intended to limit the present invention.

The first die 20 is electrically connected to the outside through the respective die pads 23 of the first die 20, the respective first conductive circuits 40 located around the chip area 1a, the respective second conductive circuits 60, and the first bonding pads 61 located around the chip area 1a on the second surface 22 of the first die 20 in turn. Thereby the FOWLP unit 1 is formed, as shown in FIG. 9.

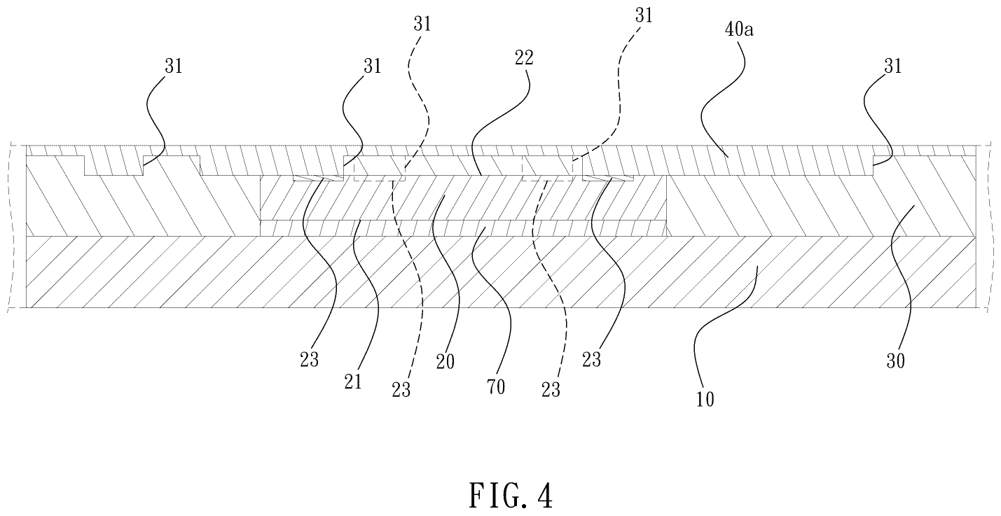

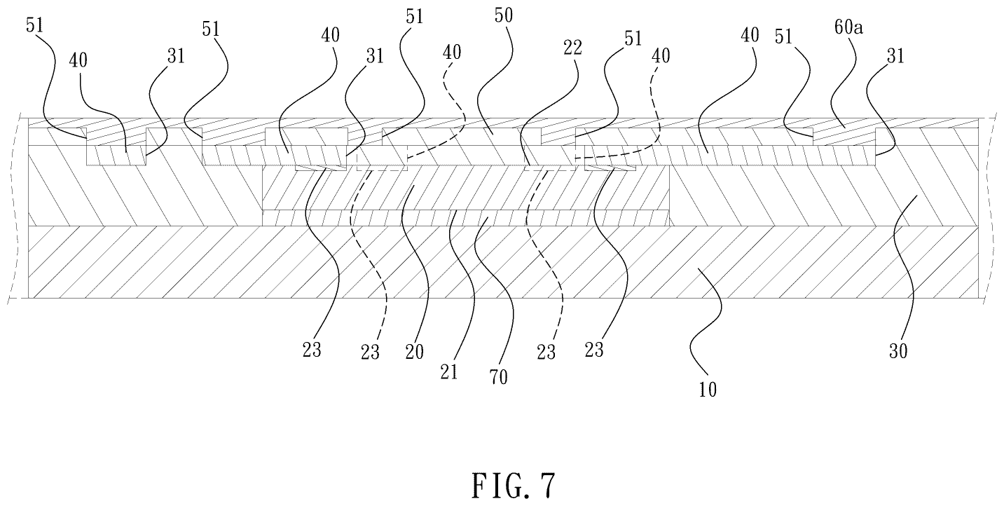

A method of manufacturing the FOWLP unit 1 includes the following steps.
Step S1: providing a substrate 10, as shown in FIG. 2.
Step S2: arranging a plurality of first dies 20 cut from at least one wafer on the substrate 10 with an interval between the two adjacent first dies 20. Each of the first dies 20 includes a first surface 21 and a second surface 22 opposite to the first surface 21. The first surface 21 of the first die 20 is arranged at the substrate 10 while the second surface 22 of the first die 20 is provided with a plurality of die pads 23. A range perpendicular to the second surface 22 of the first die 20 is defined as a chip area 1a.
Step S3: producing a plurality of first conductive circuits 40 on the second surface 22 of the first dies 20 by filling a metal paste into slots and grinding the metal paste. First paving a first dielectric layer 30 over the substrate 10 and the second surface 22 of the respective dies 20, forming a plurality of first slots 31 horizontally on the first dielectric layer 30, and exposing the die pads 23 of the first dies 20 through the first slots 31, as shown in FIG. 3. Then filling a metal paste 40a into the respective first slots 31 and allowing a level of the metal paste 40a higher than a surface of the first dielectric layer 30, as shown in FIG. 4. Lastly, grinding the metal paste 40a with the level higher than the surface of the first dielectric layer 30 to make a surface of the metal paste 40a flush with the surface of the first dielectric layer 30 and form a plurality of the first conductive circuits 40, as shown in FIG. 5.
Step S4: producing a plurality of second conductive circuits 60 on the first dielectric layer 30 by filling a metal paste into slots and grinding the metal paste. First paving a second dielectric layer 50 over the first dielectric layer 30, forming a plurality of second slots 51 horizontally on the second dielectric layer 50, and communicating the second slots 51 with the first slots 31, as shown in FIG. 6. Then filling a metal paste 60a into the respective second slots 51 and allowing a level of the metal paste 60a higher than a surface of the second dielectric layer 50, as shown in FIG. 7. Lastly, grinding the metal paste 60a with the level higher than the surface of the second dielectric layer 50 to make a surface of the metal paste 60a flush with the surface of the second dielectric layer 50 and form a plurality of the second conductive circuits 60, as shown in FIG. 8. The second conductive circuits 60 are exposed through the second slots 51 to form bonding pads in the respective second slots 51, as shown in FIG. 8. Each of the bonding pads formed in the second slots 51 around the chip area 1a on the second surface 22 of the first die 20 is a first bonding pad 61 which is electrically connected with the corresponding first conductive circuit 40 located around the chip area 1a, as shown in FIG. 9. Each of the bonding pads formed in the second slots 51 in the chip area 1a on the second surface 22 of the first die 20 is a second bonding pad 62 which is electrically connected with the corresponding first conductive circuit 40 located in the chip area 1a, as shown in FIG. 9.
Step S5: disposing a plurality of second dies 80 cut from at least one wafer over the second dielectric layer 70 by clip chip with an interval between the two adjacent second dies 80, as shown in FIG. 9. The second die 80 includes a first surface 81 and a second surface 82 opposite to each other. The second surface 82 of the second die 80 is provided with at least two die pads 83 which are electrically connected with at least two of the second bonding pads 62 by flip chip. And the second dies 80 are electrically connected with the first dies 20 by the first conductive circuits 40 in the chip area 1a, as shown in FIG. 9.
Step S6: performing cutting to form a plurality of the FOWLP units 1, as shown in FIG. 9.

Refer to FIG. 9, the first die 20 and the second die 80 are cut from the same wafer, but not limited. Thus both the first and the second dies 20, 80 have the same specification and this helps performance of superposition operation.

Refer to FIG. 9, the first die 20 and the second die 80 are cut from different wafers and having different specifications and this is beneficial to diversified applications of the product.

Refer to FIG. 2, the substrate 10 includes silicon (Si) substrate, glass substrate, and ceramic substrate. This helps diversified applications of the product.

Refer to FIG. 5 and FIG. 8, the metal pastes 40a, 60a of the first conductive circuits 40 and the second conductive circuits 60 include silver paste, nano-scale silver paste, copper paste, and nano-scale copper paste. The nano-scale silver paste has features of low cost, high conductivity, and low-temperature sintering. The nano-scale silver paste is a material available now so that no more detailed description is provided.

Refer to FIG. 9, the die pads 83 of the respective second dies 80 are electrically connected to the at least two bonding pads 61 by a solder ball 90.

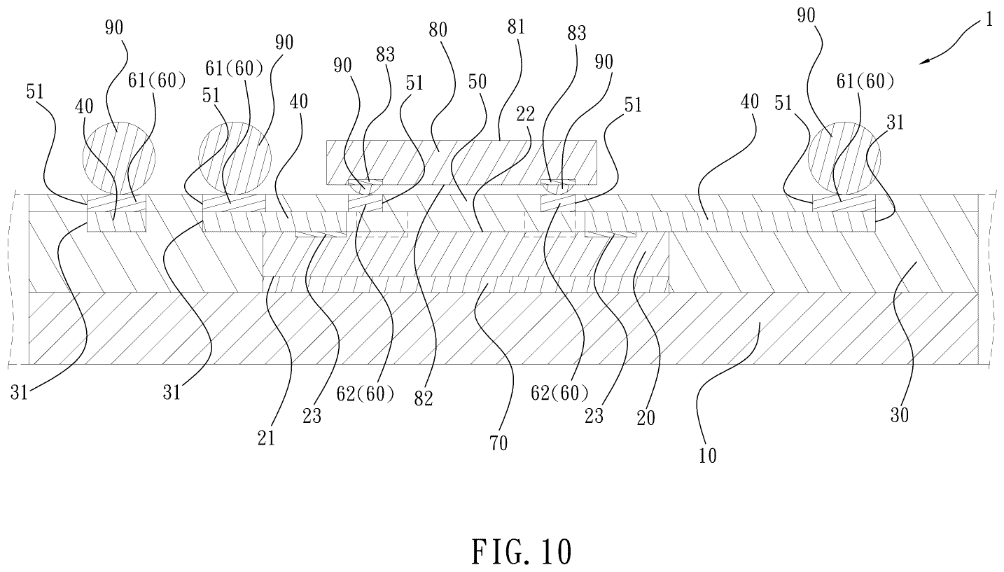

Refer to FIG. 10, a solder ball 90 is disposed on each of the second slots 51 and electrically connected to the bonding pad 61 in the second slot 51.

Refer to FIG. 1, the FOWLP unit 1 is electrically connected and mounted to a printed circuit board (PCB) 2 by the solder balls 90.

Compared with the FOWLP unit available now, the present FOWLP unit 1 has the following advantages.
(1) The steps S3-S4 of the present method of manufacturing the present FOWLP unit 1 are simplified and easily-implemented steps and this is especially helpful in reduction of a thickness of the packaging unit. Thus not only production cost is reduced, use efficiency and reliability of the FOWLP unit 1 are also improved.
(2) The plurality of the first conductive circuits 40 and the second conductive circuits 60 of the present invention are formed by filling metal paste into the slots and then grinding the metal paste. Thus the problems of the FOWLP technology available now generated during manufacturing of the respective conductive circuits including higher manufacturing cost and less environmental benefit can be solved effectively by the present invention.
(3) At least two of the die pads 83 of the second die 80 are electrically connected with at least two of the second bonding pads 62 by flip chip so that the second die 80 is located over the second dielectric layer 70 and electrically connected with the first die 20 by the respective first conductive circuits 40 in the chip area 1a (as shown in FIG. 9). Thus the multiple dies in the FOWLP are arranged more conveniently and used more efficiently.

Additional advantages and modifications will readily occur to those skilled in the art. Therefore, the invention in its broader aspects is not limited to the specific details, and representative devices shown and described herein. Accordingly, various modifications may be made without departing from the spirit or scope of the general inventive concept as defined by the appended claims and their equivalent.

1. A fan-out wafer-level packaging (FOWLP) unit comprising:
a substrate;
at least one first die cut from a wafer and provided with a first surface and a second surface opposite to the first surface; the first surface of the first die fixed on the substrate while the second surface of the first die provided with a plurality of die pads; a range perpendicular to the second surface of the first die being defined as a chip area;
a first dielectric layer mounted to the substrate and the second surface of the first die and provided with a plurality of first slots extending horizontally; wherein the die pads of the first die are exposed through the first slots correspondingly;
a plurality of first conductive circuits formed by a metal paste filled in the first slots and electrically connected with the die pads of the first die;
a second dielectric layer disposed over the first dielectric layer and provided with a plurality of second slots each of which is extending horizontally and communicating with the corresponding first slot;
a plurality of second conductive circuits formed by a metal paste filled in the second slots and electrically connected with the first conductive circuits; wherein the second slots are used for allowing the second conductive circuits to expose and form bonding pads in the second slots; wherein each of the bonding pads formed in the second slot around the chip area on the second surface of the first die is a first bonding pad which is electrically connected with the first conductive circuit located around the chip area; wherein each of the bonding pads formed in the second slot in the chip area on the second surface of the first die is a second bonding pad which is electrically connected with the first conductive circuit located in the chip area; and
at least one second die cut from a wafer and provided with a first surface and a second surface opposite to the first surface; the second surface of the second die provided with at least two die pads; wherein at least two of the die pads of the second die are electrically connected and mounted to the at least two of the second bonding pads by flip chip so that the second die is located over the second dielectric layer and electrically connected with the first die by the first conductive circuits in the chip area of the first die;
wherein the first die is electrically connected to the outside through the die pads of the first die, the first conductive circuits located around the chip area, the second conductive circuits, and the first bonding pads located around the chip area on the second surface of the first die in turn to form the FOWLP unit;
wherein a method of manufacturing the FOWLP unit comprising the steps of:
Step S1: providing a substrate;
Step S2: arranging a plurality of first dies cut from at least one wafer on the substrate with an interval between the two adjacent first dies; wherein each of the first dies includes a first surface and a second surface opposite to the first surface; the first surface of the first die is disposed on the substrate while the second surface of the first die is provided with a plurality of die pads; a range perpendicular to the second surface of the first die is defined as a chip area;
Step S3: producing a plurality of first conductive circuits on the second surface of the first dies by filling a metal paste into slots and grinding the metal paste; first paving a first dielectric layer over the substrate and the second surface of the respective dies, forming a plurality of first slots horizontally on the first dielectric layer, and exposing the die pads of the first dies through the first slots; then filling a metal paste into the first slots and allowing a level of the metal paste higher than a surface of the first dielectric layer; lastly, grinding the metal paste with the level higher than the surface of the first dielectric layer to make a surface of the metal paste flush with the surface of the first dielectric layer and form a plurality of the first conductive circuits;
S4: producing a plurality of second conductive circuits on the first dielectric layer by filling a metal paste into slots and grinding the metal paste; first paving a second dielectric layer over the first dielectric layer, forming a plurality of second slots horizontally on the second dielectric layer, and communicating the second slots with the first slots; then filling a metal paste into the second slots and allowing a level of the metal paste higher than a surface of the second dielectric layer; lastly, grinding the metal paste with the level higher than the surface of the second dielectric layer to make a surface of the metal paste flush with the surface of the second dielectric layer and form a plurality of the second conductive circuits; wherein the second conductive circuits are exposed through the second slots to form bonding pads in the second slots; wherein each of the bonding pads formed in the second slots around the chip area on the second surface of the first die is a first bonding pad which is electrically connected with the corresponding first conductive circuit located around the chip area; each of the bonding pads formed in the second slots in the chip area on the second surface of the first die is a second bonding pad which is electrically connected with the corresponding first conductive circuit located in the chip area;
Step S5: disposing a plurality of second dies cut from at least one wafer over the second dielectric layer by flip chip with an interval between the two adjacent second dies; wherein the second die includes a first surface and a second surface opposite to each other; the second surface of the second die is provided with at least two die pads; wherein at least two of the die pads of the second die are electrically connected with at least two of the second bonding pads by flip chip; and the second dies are electrically connected with the first dies by the first conductive circuits in the chip area;
Step S6: performing cutting to form a plurality of the FOWLP units.

2. The FOWLP unit as claimed in claim 1, wherein the first die and the second die are cut from the same wafer or different wafers.

3. The FOWLP unit as claimed in claim 1, wherein the substrate includes silicon (Si) substrate, glass substrate, and ceramic substrate.

4. The FOWLP unit as claimed in claim 1, wherein the metal paste which forms the first conductive circuits includes silver paste, nano-scale silver paste, copper paste, and nano-scale copper paste.

5. The FOWLP unit as claimed in claim 1, wherein the metal paste which forms the second conductive circuits includes silver paste, nano-scale silver paste, copper paste, and nano-scale copper paste.

6. The FOWLP unit as claimed in claim 1, wherein the first surface of the first die is disposed on the substrate by a die attach film (DAF).

7. The FOWLP unit as claimed in claim 1, wherein the die pads of the second die are electrically connected to at least two of the bonding pads by a solder ball.

8. The FOWLP unit as claimed in claim 1, wherein a solder ball is disposed on each of the second slots and electrically connected to the bonding pad in the second slot.

9. The FOWLP unit as claimed in claim 8, wherein the FOWLP unit is electrically connected and mounted to a printed circuit board (PCB) by the solder balls.
